(19) United States
(12) Patent Application Publication
(10) Pub. No.: US 2025/0060388 A1
(43) Pub. Date: Feb. 20, 2025

(54) DEVICE FOR SENSING WHEEL SPEED

(71) Applicant: HL MANDOO CORPORATION, Gyeonggi-do (KR)

(72) Inventors: Yong Kyun JUNG, Gyeonggi-do (KR); Jihoon CHO, Gyeonggi-do (KR)

(21) Appl. No.: 18/803,761

(22) Filed: Aug. 13, 2024

(30) Foreign Application Priority Data
Aug. 18, 2023 (KR) 10-2023-0108238

(51) Int. Cl. G01P 1/02; H01R 13/516

(52) U.S. Cl. CPC G01P 1/026; H01R 13/516

(57) ABSTRACT

A device for sensing wheel speed may include a wheel speed sensor having a sensor body with an embedded first sensor element for sensing the wheel speed of a vehicle, and a first lead frame electrically connected to the first sensor element and extending to the outside of the sensor body; a first cable having a first conductive wire electrically connected to the first lead frame and a first sheath surrounding the first conductive wire; and a first connection member arranged to surround the first lead frame and one end of the first conductive wire that is exposed to one end of the first cable and overlaps the first lead frame, and fixing the first lead frame and the first conductive wire in a contact state.

### CROSS-REFERENCE TO RELATED APPLICATION

This application claims priority to and the benefit from Korean Patent Application No. 10-2023-0108238, filed on Aug. 18, 2023, the disclosure of which is incorporated herein by reference in its entirety.

### BACKGROUND

### 1. Technical Field

The present disclosure generally relates to a device for sensing wheel speed, and more particularly, to a wheel speed sensor for detecting the rotation speed of a vehicle's wheels.

### 2. Discussion of Related Art

Various devices are installed in vehicles to improve driving and braking stability. For example, ABS (Anti-Lock Brake System) and TCS (Traction Control System) to prevent wheel slip, ESP (Electronic Stability Program) for vehicle posture control, CDC (Continuous Damping Control) which is a suspension system, EPS (Electric Power Steering) to assist steering, or the like are installed.

For control, these devices receive signals from various sensors such as yaw rate sensors, steering angle sensors, wheel speed sensors, brake pressure sensors, and lateral acceleration sensors. Among them, the wheel speed sensor is a key sensor that transmits the vehicle's wheel speed signal, and the majority of electronic control units (ECUs) use the sensing information of wheel speed sensors. Whether ABS, TCS, etc. are operated may be determined through a signal measured by the wheel speed sensor.

For power supply and signal transmission, the wheel speed sensor may be connected to the cable. Generally, a wheel speed sensor may comprise an IC chip with a lead frame, and the wire of the cable may be connected to the lead frame. Conventionally, methods such as welding are used, but there is a problem in terms of securing connection quality and process efficiency.

In addition, there is a growing need to arrange two wheel speed sensors for each wheel of the vehicle to improve detection accuracy, reliability, or redundancy. Accordingly, it is also needed to develop a sensor mounting technology that can provide assemblability and space efficiency while stably aligning the two wheel speed sensors so that the two wheel speed sensors operate stably.

### SUMMARY

The present disclosure is to solve the above problems, and is directed to providing a device for sensing wheel speed in which connection between a wheel speed sensor and a cable can be achieved efficiently.

The present disclosure is also directed to providing a device for sensing wheel speed in which connection between a cable and a lead frame is effectively achieved by exposing the lead frame of the wheel speed sensor to the outside by a wheel speed sensor holder on which the wheel speed sensor is seated.

The present disclosure is also directed to providing a device for sensing wheel speed in which connection between a lead frame of a wheel speed sensor and a cable is easily achieved while the cable and a connection member are coupled to a cable holder.

The present disclosure is also directed to providing a device for sensing wheel speed in which a plurality of wheel speed sensors are efficiently aligned and connected to a cable.

The present disclosure is also directed to providing a device for sensing wheel speed in which arrangement and alignment of a plurality of cables are effectively achieved.

The objects of the present disclosure are not limited to the above-described objects, and other objects that are not mentioned will be able to be clearly understood by those skilled in the art to which the present disclosure pertains from the following description.

According to an aspect of the present disclosure, provided is a device for sensing wheel speed, including: a wheel speed sensor having a sensor body with an embedded first sensor element for sensing the wheel speed of a vehicle, and a first lead frame electrically connected to the first sensor element and extending to the outside of the sensor body; a first cable having a first conducting wire electrically connected to the first lead frame and a first sheath surrounding the first conducting wire; and a first connection member arranged to surround the first lead frame and one end of the first conducting wire that is exposed to one end of the first cable and overlaps the first lead frame, and fixing the first lead frame and the first conducting wire in a contact state.

In the device for sensing wheel speed according to an aspect of the present disclosure, the first connection member may have a first connection body, and a first connection hole penetrating one side and the other side of the first connection body and in which the first lead frame and one end of the first conducting wire are disposed to overlap.

In the device for sensing wheel speed according to an aspect of the present disclosure, the first connection body may have a rectangular box shape, and the first connection hole may have a rectangular shape.

In the device for sensing wheel speed according to an aspect of the present disclosure, the wheel speed sensor may further have a second lead frame electrically connected to the first sensor element and extending to the outside of the sensor body, and the device for sensing wheel speed may further include: a second cable having a second conducting wire electrically connected to the second lead frame and a second sheath surrounding the second conducting wire; and a second connection member arranged to surround the second lead frame and one end of the second conducting wire that is exposed to one end of the second cable and overlaps the lead frame, and fixing the second lead frame and the second conducting wire in a contact state.

In the device for sensing wheel speed according to an aspect of the present disclosure, the first connection member and the second connection member may be arranged side by side.

The device for sensing wheel speed according to an aspect of the present disclosure may further include a wheel speed sensor holder on which the wheel speed sensor is seated.

In the device for sensing wheel speed according to an aspect of the present disclosure, the wheel speed sensor holder may include a seating part on which the sensor body is seated; and a support part connected to the seating part and supporting the first and second lead frames.

In the device for sensing wheel speed according to an aspect of the present disclosure, the support part may have a shorter length than the first and second lead frames.

The device for sensing wheel speed according to an aspect of the present disclosure may further include a cable holder on which the first and second cables are seated.

In the device for sensing wheel speed according to an aspect of the present disclosure, the first and second connection members may be fixedly disposed in the cable holder.

In the device for sensing wheel speed according to an aspect of the present disclosure, the cable holder may include a connection part having first and second through holes in which the first and second lead frames are inserted and disposed through the front, respectively, and each one end of the first and second conducting wires are inserted and disposed through the rear, respectively, and in which the first and second connection members are fixedly disposed, respectively.

In the device for sensing wheel speed according to an aspect of the present disclosure, the cable holder may further include a cable support part connected to the rear of the connection part and extending to support the first and second cables.

The device for sensing wheel speed according to an aspect of the present disclosure may further include an additional sheathing member disposed at the rear of the cable support part and surrounding the first and second cables.

In the device for sensing wheel speed according to an aspect of the present disclosure, the cable holder may further include an additional sheathing member support part connected to the rear of the cable support part and on which the additional sheathing member is seated and supported.

According to another aspect of the present disclosure, provided is a device for sensing wheel speed, including: a wheel speed sensor having a sensor body with an embedded first sensor element and an embedded second sensor element for sensing the wheel speed of a vehicle, and first and second lead frames electrically connected to the first sensor element and extending to the outside of the sensor body, and third and fourth lead frames electrically connected to the second sensor element and extending to the outside of the sensor body; a first cable having a first conducting wire electrically connected to the first lead frame and a first sheath surrounding the first conducting wire; a second cable having a second conducting wire electrically connected to the second lead frame and a second sheath surrounding the second conducting wire; a third cable having a third conducting wire electrically connected to the third lead frame and a third sheath surrounding the third conducting wire; a fourth cable having a fourth conducting wire electrically connected to the fourth lead frame and a fourth sheath surrounding the fourth conducting wire; a first connection member arranged to surround the first lead frame and one end of the first conducting wire that is exposed to one end of the first cable and overlaps the first lead frame, and fixing the first lead frame and the first conducting wire in a contact state; a second connection member arranged to surround the second lead frame and one end of the second conducting wire that is exposed to one end of the second cable and overlaps the second lead frame, and fixing the second lead frame and the second conducting wire in a contact state; a third connection member arranged to surround the third lead frame and one end of the third conducting wire that is exposed to one end of the third cable and overlaps the third lead frame, and fixing the third lead frame and the third conducting wire in a contact state; a fourth connection member arranged to surround the fourth lead frame and one end of the fourth conducting wire that is exposed to one end of the fourth cable and overlaps the fourth lead frame, and fixing the fourth lead frame and the fourth conducting wire in a contact state; and a cable holder having a connection part having first to fourth through holes in which the first to fourth lead frames are inserted and disposed through the front, respectively, and each one end of the first to fourth conducting wires are inserted and disposed through the rear, respectively.

In the device for sensing wheel speed according to another aspect of the present disclosure, the first to fourth connection members may be fixedly disposed in the first to fourth through holes, respectively.

In the device for sensing wheel speed according to another aspect of the present disclosure, the first to fourth connection members may be arranged side by side.

In the device for sensing wheel speed according to another aspect of the present disclosure, the first connection member may have a first connection body, and a first connection hole penetrating one side and the other side of the first connection body and in which the first lead frame and one end of the first conducting wire are disposed to overlap, and the second to fourth connection members may have second to fourth connection bodies corresponding to the first connection body and second to fourth connection holes corresponding to the first connection hole, respectively.

In the device for sensing wheel speed according to another aspect of the present disclosure, the first connection body may have a rectangular box shape, and the first connection hole may have a rectangular shape.

The device for sensing wheel speed according to another aspect of the present disclosure may further include a wheel speed sensor holder on which the wheel speed sensor is seated.

In the device for sensing wheel speed according to another aspect of the present disclosure, the wheel speed sensor holder may include a seating part on which the sensor body is seated; and a support part connected to the seating part and supporting the first to fourth lead frames.

In the device for sensing wheel speed according to another aspect of the present disclosure, the support part may have a shorter length than the first to fourth lead frames.

In the device for sensing wheel speed according to another aspect of the present disclosure, the cable holder may be connected to the rear of the connection part, and the device for sensing wheel speed may further include a cable support part extending to support the first to fourth cables.

The device for sensing wheel speed according to another aspect of the present disclosure may further include an additional sheathing member disposed at the rear of the cable support part and surrounding the first to fourth cables.

In the device for sensing wheel speed according to another aspect of the present disclosure, the first to fourth cables may be arranged in two rows and two columns inside the additional sheathing member.

In the device for sensing wheel speed according to another aspect of the present disclosure, the cable holder may further include an additional sheathing member support part connected to the rear of the cable support part and on which the additional sheathing member is seated and supported.

In the device for sensing wheel speed according to another aspect of the present disclosure, the bottom surface of the cable support part may include a portion inclined upward from the additional sheathing member support part side to the connection part side.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a front perspective view of a device for sensing wheel speed according to an exemplary embodiment of the present disclosure.

FIG. 2 is a rear perspective view of a device for sensing wheel speed according to an exemplary embodiment of the present disclosure.

FIG. 3 is a view illustrating a device for sensing wheel speed without a housing according to an exemplary embodiment of the present disclosure.

FIG. 4 is an exploded view in which a wheel speed sensor assembly and a cable of a device for sensing wheel speed are separated according to an exemplary embodiment of the present disclosure.

FIG. 5 is an exploded view in which a wheel speed sensor assembly and a wheel speed sensor holder of a device for sensing wheel speed are separated according to an exemplary embodiment of the present disclosure.

FIG. 6 is a view in which a cable, a connection member or connector, and a cable holder of a device for sensing wheel speed are coupled according to an exemplary embodiment of the present disclosure.

FIG. 7 is a view in which a cable and a cable holder of a device for sensing wheel speed are separated according to an exemplary embodiment of the present disclosure.

FIG. 8 is an upper perspective view of a connection member or connector of a device for sensing wheel speed according to an exemplary embodiment of the present disclosure.

FIG. 9 is a lower perspective view of a connection member or connector of a device for sensing wheel speed according to an exemplary embodiment of the present disclosure.

FIG. 10 is a view illustrating a longitudinal cross-section of a device for sensing wheel speed according to an exemplary embodiment of the present disclosure.

FIG. 11 is a longitudinal cross-sectional perspective view of a cable holder of a device for sensing wheel speed according to an exemplary embodiment of the present disclosure.

FIG. 12 is a view illustrating a modified example of a wheel speed sensor assembly and a wheel speed sensor holder of a device for sensing wheel speed according to an exemplary embodiment of the present disclosure.

### DETAILED DESCRIPTION OF EXEMPLARY EMBODIMENTS

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their invention.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

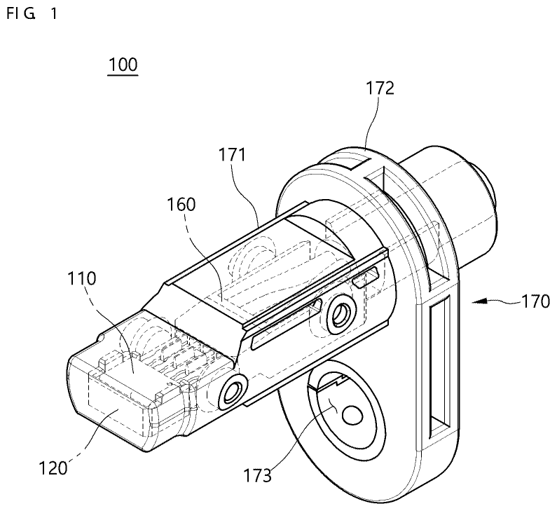

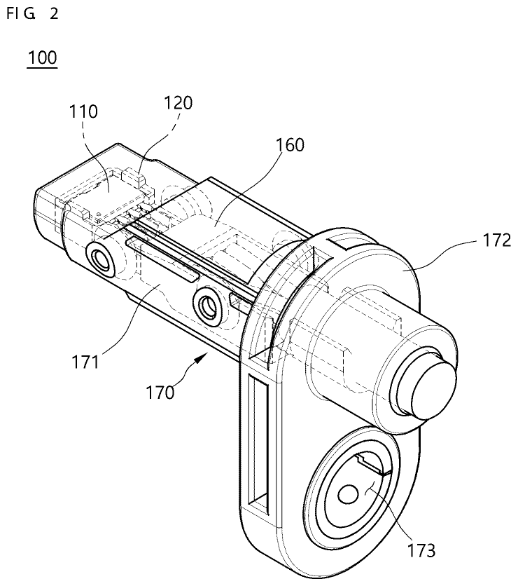

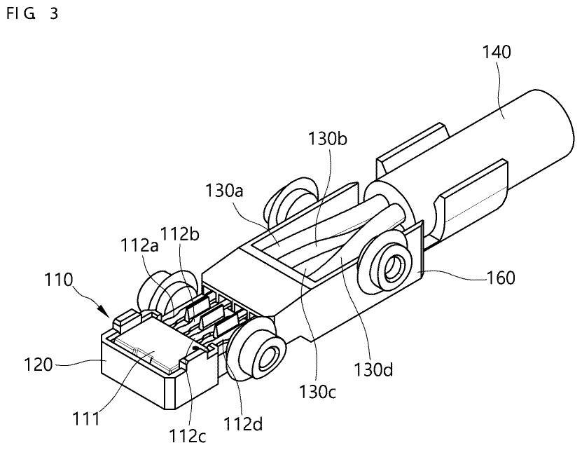

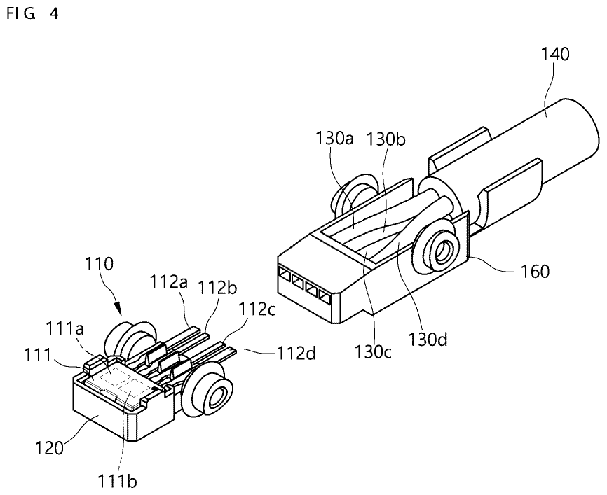

FIG. 1 is a front perspective view of a device for sensing wheel speed according to an exemplary embodiment of the present disclosure. FIG. 2 is a rear perspective view of a device for sensing wheel speed according to an exemplary embodiment of the present disclosure. In addition, FIG. 3 is a view illustrating a device for sensing wheel speed without a housing according to an exemplary embodiment of the present disclosure. FIG. 4 is an exploded view in which a wheel speed sensor assembly and a cable of a device for sensing wheel speed are separated according to an exemplary embodiment of the present disclosure.

The device for sensing wheel speed 100 according to an embodiment of the present disclosure may detect the rotation of a tone wheel or encoder coupled to a wheel of a vehicle. The tone wheel or encoder rotates together with the wheel of the vehicle, and the device for sensing wheel speed 100 according to an embodiment of the present disclosure may detect the number of revolutions of the tone wheel or encoder.

Referring to FIGS. 1 to 4, the device for sensing wheel speed 100 according to an embodiment of the present disclosure may include a wheel speed sensor assembly 110, a wheel speed sensor holder 120, first to fourth cables 130a, 130b, 130c, and 130d, an additional sheathing member 140, first to fourth connection members or connectors 150a, 150b, 150c, and 150d, a cable holder 160, and a housing 170.

The wheel speed sensor assembly 110 may include a sensor body 111 and first to fourth lead frames 112a, 112b, 112c, 112d.

A first sensor element 111a and a second sensor element 111b for sensing a wheel speed of a vehicle may be embedded in the sensor body 111. The first sensor element 111a and the second sensor element 111b may detect a tone wheel or an encoder that rotates together with the wheel of the vehicle. For example, the first sensor element 111a and the second sensor element 111b may be hall sensors.

In an embodiment of the present disclosure, the first sensor element 111a and the second sensor element 111b may be arranged side by side inside the sensor body 111. For example, the first sensor element 111a and the second sensor element 111b may be arranged side by side in the horizontal direction inside the sensor body 111.

Each of the first sensor element 111a and the second sensor element 111b may be configured as a separate die. In addition, the sensor body 111 may be configured by assembling or molding two dies into one.

The first and second lead frames 112a and 112b are electrically connected to the first sensor element 111a and extend to the outside of the sensor body 111. The first lead frame 112a may connect the first sensor element 111a and a power source. In addition, the second lead frame 112b may transmit the sensing information of the first sensor element 111a to the outside (e.g., ECU).

Alternatively, the first lead frame 112a may transmit the sensing information of the first sensor element 111a to the outside, and the second lead frame 112b may be connected to a power source.

The first lead frame 112a and the second lead frame 112b may be arranged side by side with each other. In more detail, the first lead frame 112a and the second lead frame 112b may be arranged side by side in the horizontal direction. In addition, the first lead frame 112a and the second lead frame 112b may have the same length.

The third and fourth lead frames 112c and 112d are electrically connected to the second sensor element 111b and extend to the outside of the sensor body 111. The third lead frame 112c may connect the second sensor element 111b and a power source. In addition, the fourth lead frame 112d may transmit the sensing information of the second sensor element 111b to the outside (e.g., ECU).

Alternatively, the third lead frame 112c may transmit the sensing information of the second sensor element 111b to the outside, and the fourth lead frame 112d may be connected to a power source.

The third lead frame 112c and the fourth lead frame 112d may be arranged side by side with each other. For instance, the third lead frame 112c and the fourth lead frame 112d may be arranged side by side in the horizontal direction. In addition, the third lead frame 112c and the fourth lead frame 112d may have the same length.

The first to fourth lead frames 112a, 112b, 112c, and 112d may be arranged side by side in the horizontal direction. In addition, the first to fourth lead frames 112a, 112b, 112c, and 112d may have the same length.

In this way, when the wheel speed sensor assembly 110 is configured such that the first sensor element 111a and the second sensor element 111b are embedded in one sensor body 111, space required for arranging the two sensor elements may be reduced or minimized. In addition, the arrangement of the two sensor elements may also be made through a single process. Accordingly, space efficiency and assemblability can be improved.

The wheel speed sensor holder 120 accommodates the wheel speed sensor assembly 110. The wheel speed sensor assembly 110 may be seated on the wheel speed sensor holder 120.

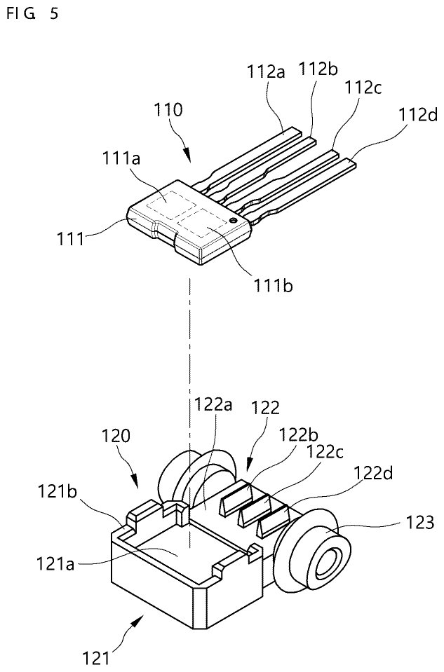

FIG. 5 is an exploded view in which a wheel speed sensor assembly and a wheel speed sensor holder of a device for sensing wheel speed are separated according to an exemplary embodiment of the present disclosure.

Referring to FIG. 5, the wheel speed sensor holder 120 may include a seat part 121 and a support part 122.

The seat part 121 accommodates the sensor body 111. The sensor body 111 may be seated on the seat part 121. In an embodiment of the present disclosure, the seat part 121 may include a sensor seat plate 121a on which the bottom surface of the sensor body 111 is seated, and a sensor support sidewall 121b protruding upward from the sensor seating plate 121a to support the side surface of the sensor body 111. The sensor support sidewall 121b may be provided to surround the remaining portion of the side surface of the sensor body 111 except for a portion where the lead frame extends.

The support part 122 is connected to the seat part 121. The support part 122 supports the first to fourth lead frames 112a, 112b, 112c, and 112d. The support part 122 may have a length shorter than those of the first to fourth lead frames 112a, 112b, 112c, and 112d. Accordingly, when the first to fourth lead frames 112a, 112b, 112c, and 112d approach the wheel speed sensor holder 120 toward the cable holder 160 to be described later to connect the first to fourth cables 130a, 130b, 130c, and 130d, interference may not occur, and connection between the lead frame and the cable may be easily performed.

The support part 122 may include a lead frame support plate 122a supporting the first to fourth lead frames 112a, 112b, 112c, and 112d, and a plurality of lead frame support sidewalls 122b, 122c, and 122d protruding upward from the lead frame support plate 122a to support side surfaces of the first to fourth lead frames 112a, 112b, 112c, and 112d between the first lead frame 112a and the second lead frame 112b, between the second lead frame 112b and the third lead frame 112c, and between the third lead frame 112c and the fourth lead frame 112d.

Widths of the plurality of lead frame support sidewalls 122b, 122c, and 122d may be formed to be wider at the lower side than at the upper side. This structure may allow the first to fourth lead frames 112a, 112b, 112c, and 112d to easily enter toward the lead frame support plate 122a from the upper side of the lead frame support plate 122a. In addition, this structure may enable the first to fourth lead frames 112a, 112b, 112c, and 112d to be stably supported after the wheel speed sensor assembly 110 is seated on the wheel speed sensor holder 120.

In an embodiment of the present disclosure, the wheel speed sensor holder 120 may have one or more side beams 123. The side beam 123 may be disposed to extend laterally from both sides of the seat part 121 or the support part 122. For example, the side beam 123 may be disposed to extend laterally from both sides of the lead frame support plate 122a. The side beam 123 may be used to fix the housing 170 in a mold when molding the housing 170.

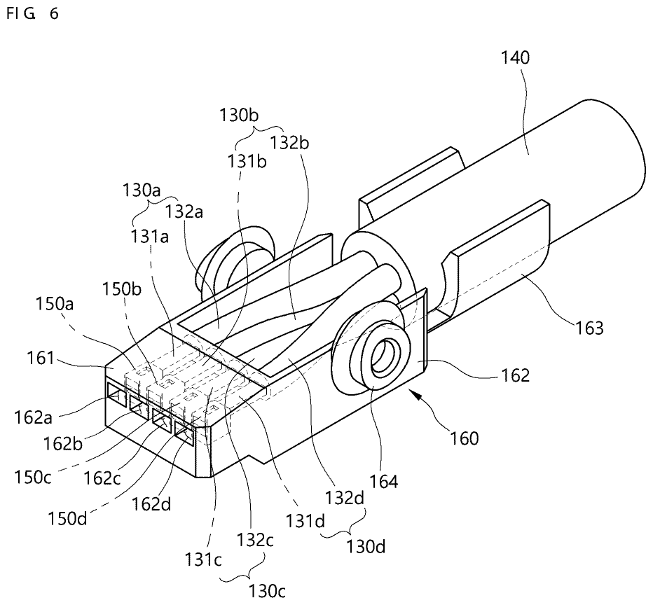

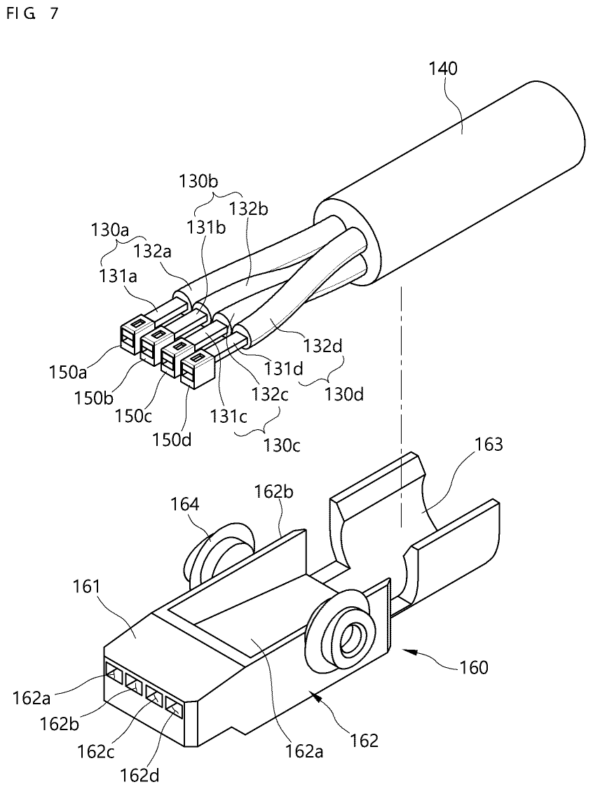

FIG. 6 is a view a cable, a connection member or connector, and a cable holder of a device for sensing wheel speed are coupled according to an exemplary embodiment of the present disclosure. In addition, FIG. 7 is an exploded view in which a cable and a cable holder of a device for sensing wheel speed are separated according to an exemplary embodiment of the present disclosure.

Referring to FIGS. 6 and 7, the first cable 130a has a first conductive wire 131a electrically connected to the first lead frame 112a and a first sheath 132a covering or surrounding the first conductive wire 131a. The second cable 130b has a second conductive wire 131b electrically connected to the second lead frame 112b and a second sheath 132b surrounding the second conductive wire 131b.

The first conductive wire 131a may be for supplying power. The second conductive wire 131b may be for transmitting a signal. Alternatively, the first conductive wire 131a may be for transmitting a signal, and the second conductive wire 131b may be for supplying power.

The first sheath 132a insulates the first conductive wire 131a from the outside. In addition, the second sheath 132b insulates the second conductive wire 131b from the outside of the first cable 130a.

One end of the first conductive wire 131a is exposed out of one end of the first sheath 132a of the first cable 130a. One end of the first conductive wire 131a exposed to one end of the first cable 130a is connected to the first lead frame 112a. In an embodiment of the present disclosure, one end of the first conductive wire 131a may be disposed to overlap or contact the first lead frame 112a.

One end of the second conductive wire 131b is exposed to one end of the second sheath 132b of the second cable 130b. One end of the second conductive wire 131b exposed to one end of the second cable 130b is connected to the second lead frame 112b. In an embodiment of the present disclosure, one end of the second conductive wire 131b may be disposed to overlap or contact the second lead frame 112b.

Referring to FIGS. 6 and 7, the third cable 130c has a third conductive wire 131c electrically connected to the third lead frame 112c and a third sheath 132c covering or surrounding the third conductive wire 131c. The fourth cable 130d has a fourth conductive wire 131d electrically connected to the fourth lead frame 112d and a fourth sheath 132d surrounding the fourth conductive wire 131d.

The third conductive wire 131c may be for supplying power. The fourth conductive wire 131d may be for transmitting a signal. Alternatively, the third conductive wire 131c may be for transmitting a signal, and the fourth conductive wire 131d may be for supplying power.

In addition, the third sheath 132c insulates the third conductive wire 131c from the outside of the third conductive wire 131c. In addition, the fourth sheath 132d insulates the fourth conductive wire 131d from the outside of the fourth sheath 132d.

One end of the third conductive wire 131c is exposed out of the third sheath 132c of one end of the third cable 130c. One end of the third conductive wire 131c exposed to one end of the third cable 130c is connected to the third lead frame 112c. In an embodiment of the present disclosure, one end of the third conductive wire 131c may be disposed to overlap or contact the third lead frame 112c.

One end of the fourth conductive wire 131d is exposed out of the fourth sheath 132d of one end of the fourth cable 130d. One end of the fourth conductive wire 131d exposed to one end of the fourth cable 130d is connected to the fourth lead frame 112d. In an embodiment of the present disclosure, one end of the fourth conductive wire 131d may be disposed to overlap or contact the fourth lead frame 112d.

Meanwhile, each one end of the first to fourth conductive wires 131a, 131b, 131c, and 131d exposed to respective one end of the first to fourth cables 130a, 130b, 130c, and 130d may be disposed in a compressed state. In more detail, since the contact surfaces of the first to fourth lead frames 112a, 112b, 112c, and 112d are formed substantially flat, each one end of the first to fourth conductive wires 131a, 131b, 131c, and 131d exposed to respective one end of the first to fourth cables 130a, 130b, 130c, and 130d to increase a contact area may be compressed in a substantially rectangular rod shape.

The additional sheathing member 140 is arranged to cover or surround the first to fourth cables 130a, 130b, 130c, and 130d. The additional sheathing member 140 may have a substantially cylindrical shape.

Referring to FIGS. 6 and 7, the first to fourth cables 130a, 130b, 130c, and 130d may be arranged in two rows and two columns inside the additional sheathing member 140.

When the first to fourth cables 130a, 130b, 130c, and 130d are respectively connected to the outside of the device for sensing wheel speed 100, twisting, interference, and the like between cables may occur. The additional sheathing member 140 makes the first to fourth cables 130a, 130b, 130c, and 130d into one composite cable, thereby increasing the efficiency of wiring between the device for sensing wheel speed 100 and an external power source or ECU.

The first to fourth cables 130a, 130b, 130c, and 130d may be exposed to one end of the additional sheathing member 140. That is, the first to fourth cables 130a, 130b, 130c, and 130d are exposed to one end of the additional sheathing member 140. In addition, the first to fourth conductive wires 131a, 131b, 131c, and 131d may be respectively exposed to one end of the first to fourth cables 130a, 130b, 130c, and 130d exposed to one end of the additional sheathing member 140.

Based on the cable holder 160 to be described later, the additional sheathing member 140 may be arranged behind a cable support part 162 of the cable holder 160 to surround the first to fourth cables 130a, 130b, 130c, and 130d.

A first connection member or connector 150a is arranged to cover or surround the first lead frame 112a and one end of the first conductive wire 131a that is exposed to one end of the first cable 130a and overlaps or contacts the first lead frame 112a. The first connection member or connector 150a fixes the first lead frame 112a and the first conductive wire 131a in a contact state.

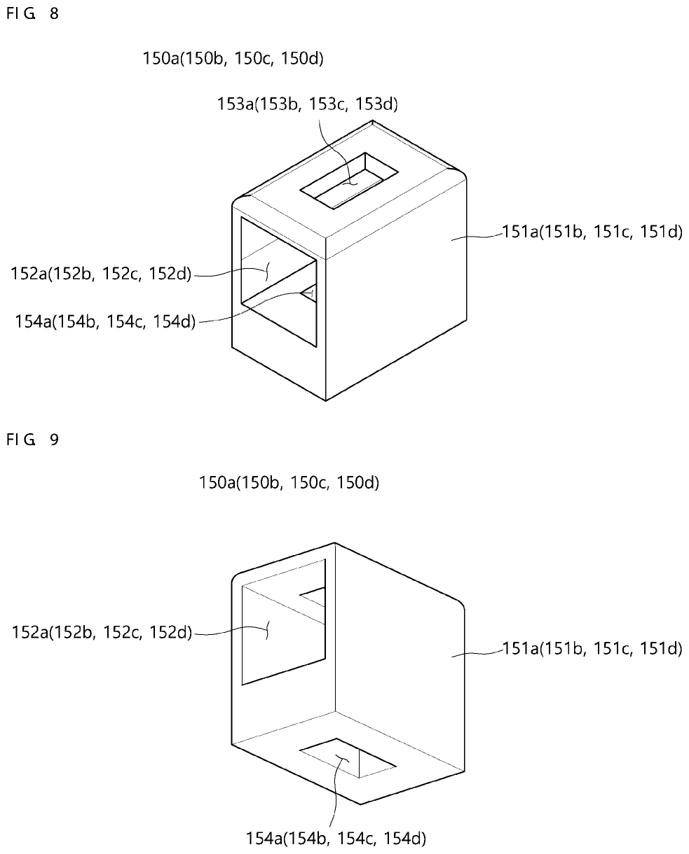

FIG. 8 is an upper perspective view of a connection member or connector of a device for sensing wheel speed according to an exemplary embodiment of the present disclosure. In addition, FIG. 9 is a lower perspective view of a connection member or connector of a device for sensing wheel speed according to an exemplary embodiment of the present disclosure.

Referring to FIGS. 8 and 9, the first connection member or connector 150a may have a first connection body 151a, and a first connection hole 152a penetrating one side and the other side of the first connection body 151a and in which the first lead frame 112a and one end of the first conductive wire 131a are disposed to overlap or contact each other. In this case, the first connection body 151a may have a substantially rectangular box shape, and the first connection hole 152a may have a substantially rectangular shape.

The first lead frame 112a and one end of the first conductive wire 131a are arranged to be stacked in an overlapping manner inside the first connection hole 152a, and the first lead frame 112a and the first conductive wire 131a may be fixed in a contact state by the first connection body 151a. As described above, since the first lead frame 112a and one end of the first conductive wire 131a have a substantially rectangular rod shape, a contact state may be efficiently maintained inside the first connection hole 152a having a substantially rectangular shape.

A second connection member or connector 150b is arranged to cover or surround the second lead frame 112b and one end of the second conductive wire 131b that is exposed to one end of the second cable 130b and overlaps or contacts the second lead frame 112b. The second connection member or connector 150b fixes the second lead frame 112b and the second conductive wire 131b in a contact state.

A third connection member or connector 150c is arranged to surround or cover the third lead frame 112c and one end of the third conductive wire 131c that is exposed to one end of the third cable 130c and overlaps or contacts the third lead frame 112c. The third connection member or connector 150c fixes the third lead frame 112c and the third conductive wire 131c in a contact state.

A fourth connection member or connector 150d is arranged to cover or surround the fourth lead frame 112d and one end of the fourth conductive wire 131d that is exposed to one end of the fourth cable 130d and overlaps or contacts the fourth lead frame 112d. The fourth connection member or connector 150d fixes the fourth lead frame 112d and the fourth conductive wire 131d in a contact state.

Referring to FIGS. 8 and 9, the second to fourth connection members or connectors 150b, 150c, and 150d may have a connection body corresponding to the first connection body 151a and a connection hole corresponding to the first connection hole 152a, respectively. That is, the second to fourth connection members or connectors 150b, 150c, and 150d may have second to fourth connection bodies 151b, 151c, and 151d and second to fourth connection holes 152b, 152c, and 152d, respectively. In this case, the second to fourth connection bodies 151b, 151c, and 151d may have a substantially rectangular box shape, and the second to fourth connection holes 152b, 152c, and 152d may have a substantially rectangular shape.

In an embodiment of the present disclosure, the first to fourth connection members or connectors 150a, 150b, 150c, and 150d may be arranged side by side. Accordingly, connection between the first to fourth lead frames 112a, 112b, 112c, and 112d and the first to fourth conductive wires 131a, 131b, 131c, and 131d may be efficiently achieved.

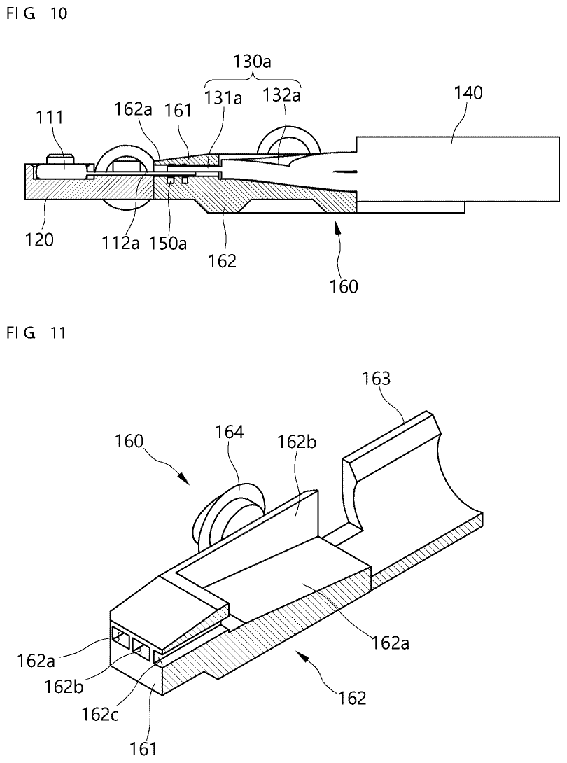

FIG. 10 is a view illustrating a longitudinal cross-section of a device for sensing wheel speed according to an exemplary embodiment of the present disclosure.

Referring to FIG. 10, in an embodiment of the present disclosure, the first connection member or connector 150a is fixedly placed in the connection part 161 of the cable holder 160, which will be described later, while being inserted into one end of the first conductive wire 131a of the first cable 130a. For instance, the cable holder 160 may be double-injected while the first cable 130a and the first connection member or connector 150a are coupled. During the injection process, upper and lower ends of the connection member or connector 150a may be embedded in the connection part 161 of the cable holder 160.

In this regard, the first connection member or connector 150a may have a first upper through hole 153a penetrating the top surface of the first connection hole 152a, and a first lower through hole 154a penetrating the bottom surface of the first connection hole 152a. The first upper through hole 153a and the first lower through hole 154a increase the contact area between the connection part 161 and the first connection member or connector 150a when the cable holder 160 is double-injected while the first cable 130a and the first connection member or connector 150a are coupled. Accordingly, the first connection member or connector 150a may be stably fixed to the connection part 161 of the cable holder 160.

Meanwhile, the second to fourth connection members or connectors 150b, 150c, and 150d may have second to fourth upper through holes 153b, 153c, and 153d penetrating top surfaces of the second to fourth connection holes 152b, 152c, and 152d, and second to fourth lower through holes 154b, 154c, and 154d penetrating bottom surfaces of the second to fourth connection holes 152b, 152c, and 152d.

The second to fourth upper through holes 153b, 153c, and 153d and the second to fourth lower through holes 154b, 154c, and 154d increase the contact area between the connection part 161 and the second to fourth connection members or connectors 150b, 150c, and 150d when the cable holder 160 is double-injected while the second to fourth cables 130b, 130c, and 130d and the second to fourth connection members or connectors 150b, 150c, and 150d are coupled. Accordingly, the second to fourth connection members or connectors 150b, 150c, and 150d may be stably fixed to the connection part 161 of the cable holder 160.

The cable holder 160 supports the first to fourth cables 130a, 130b, 130c, and 130d. In other words, the first to fourth cables 130a, 130b, 130c, and 130d may be seated on the cable holder 160.

Referring to FIGS. 6 and 7, the cable holder 160 may include a connection part 161, a cable support part 162, and an additional sheathing member support part 163.

As described above, the cable holder 160 may be made by a double injection method in a state in which the first to fourth cables 130a, 130b, 130c, and 130d and the first to fourth connection members or connectors 150a, 150b, 150c, and 150d are coupled. In this case, the first to fourth connection members or connectors 150a, 150b, 150c, and 150d may be fixedly disposed in the cable holder 160. For example, as shown in FIG. 10, the first to fourth connection members or connectors 150a, 150b, 150c, and 150d may be embedded in the cable holder 160.

The connection part 161 has first to fourth through holes 162a, 162b, 162c, and 162d in which the first to fourth lead frames 112a, 112b, 112c, and 112d are inserted and disposed through the front of the first to fourth through holes 162a, 162b, 162c, and 162d, respectively, and each one end of the first to fourth conductive wires 131a, 131b, 131c, and 131d are inserted and disposed through the rear of the first to fourth through holes 162a, 162b, 162c, and 162d, respectively. The connection part 161 may have a box shape as a whole. In addition, the first to fourth through holes 162a, 162b, 162c, and 162d may pass through the connection part 161 in the front-rear direction and may be placed side by side with each other. For example, the first to fourth through holes 162a, 162b, 162c, and 162d may be arranged side by side in a horizontal direction.

First to fourth connection members or connectors 150a, 150b, 150c, and 150d may be fixedly disposed in the first to fourth through holes 162a, 162b, 162c, and 162d, respectively. That is, they may be fixedly disposed in the first to fourth through holes 162a, 162b, 162c, and 162d. As described above, first to fourth connection members or connectors 150a, 150b, 150c, and 150d may be embedded in the first to fourth through holes 162a, 162b, 162c, and 162d, respectively.

The cable support part 162 is extended to support the first to fourth cables 130a, 130b, 130c, and 130d. The cable support part 162 may be connected to the rear of the connection part 161.

The cable support part 162 may include a cable support plate 162a disposed to support the first to fourth cables 130a, 130b, 130c, and 130d from a lower side, and a cable support sidewall 162b extending upward from both sides of the cable support plate 162a to support the sides of the first to fourth cables 130a, 130b, 130c, and 130d.

The additional sheathing member support part 163 is connected to the rear of the cable support part 162. The additional sheathing member support part 163 supports the additional sheathing member 140. That is, the additional sheathing member 140 may be seated and supported on the additional sheathing member support part 163. The additional sheathing member support part 163 may have a ring shape with an open upper side so as to cover or surround a part of the outer circumferential surface of the additional sheathing member 140.

FIG. 11 is a longitudinal cross-sectional perspective view of a cable holder of a device for sensing wheel speed according to an exemplary embodiment of the present disclosure.

Referring to FIG. 11, in an embodiment of the present disclosure, the bottom surface of the cable support part 162 may include a portion inclined upward from the additional sheathing member support part 163 side to the connection part 161 side. In other words, the bottom surface of the cable support part 162 may include a portion inclined downward from the front to the rear. Alternatively, the bottom surface of the cable support part 162 may include a portion inclined upward from the rear to the front.

For example, the bottom surface of the cable support plate 162a of the cable support part 162 may include a portion inclined upward from the additional sheathing member support part 163 side to the connection part 161 side. In other words, the bottom surface of the cable support plate 162a may include a portion inclined downward from the front to the rear. Alternatively, the bottom surface of the cable support plate 162a may include a portion inclined upward from the rear to the front.

As mentioned earlier, the first to fourth cables 130a, 130b, 130c, and 130d may be arranged in two rows and two columns inside the additional sheathing member 140. Meanwhile, the first to fourth through holes 162a, 162b, 162c, and 162d may be arranged side by side in a horizontal direction.

As shown in FIGS. 4 and 6, the first cable 130a and the fourth cable 130d disposed on the upper side are disposed on the same horizontal plane as the first to fourth through holes 162a, 162b, 162c, and 162d of the connection part 161 so that they may easily enter the first through hole 162a and the fourth through hole 162d, respectively. However, the second cable 130b and the third cable 130c placed on the lower side are placed at a lower position than the first to fourth through holes 162a, 162b, 162c, and 162d, so the cables need to be bent upward to enter the second through hole 162b and the third through hole 162c.

As shown in FIG. 10, when the bottom surface of the cable support plate 162a of the cable support part 162 includes a portion inclined upward from the additional sheathing member support part 163 side to the connection part 161 side, the second cable 130b and the third cable 130c disposed on the lower side may be smoothly guided upward. Accordingly, the second cable 130b and the third cable 130c can easily enter the second through hole 162b and the third through hole 162c.

In an embodiment of the present disclosure, the cable holder 160 may have one or more side beams 164. The side beam 164 may be disposed to extend laterally from both sides of the cable support part 162. The side beam 164 may be used to fix the housing 170 in a mold when molding the housing 170.

The housing 170 accommodates the wheel speed sensor assembly 110, the wheel speed sensor holder 120, the first to fourth cables 130a, 130b, 130c, and 130d, the additional sheathing member 140, and the first to fourth connection members or connectors 150a, 150b, 150c, and 150d, and the cable holder 160.

The housing 170 may be formed by molding in a state in which the wheel speed sensor assembly 110, the wheel speed sensor holder 120, the first to fourth cables 130a, 130b, 130c, and 130d, the additional sheathing member 140, and the first to fourth connection members or connectors 150a, 150b, 150c, and 150d, and the cable holder 160 are combined.

In an embodiment of the present disclosure, the housing 170 may include a housing body 171 and a fastening member 172.

The housing body 171 accommodates the wheel speed sensor assembly 110, the wheel speed sensor holder 120, the first to fourth cables 130a, 130b, 130c, and 130d, the additional sheathing member 140, and the first to fourth connection members or connectors 150a, 150b, 150c, and 150d, and the cable holder 160 therein.

The fastening member 172 is a portion to which a fastening member for fastening the device for sensing wheel speed 100 to the vehicle body is coupled. The fastening member 172 may include a portion connected to the housing body 171 and extending downward. In addition, the fastening member 172 may include a through hole 173 for fastening the fastening member.

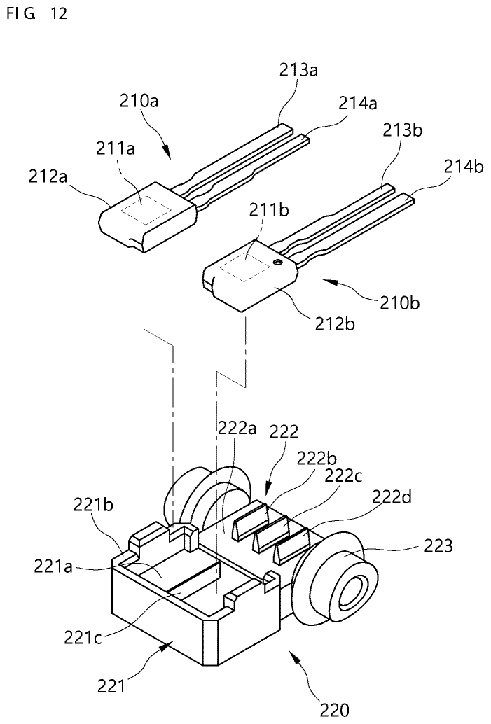

FIG. 12 is a view illustrating a modified example of a wheel speed sensor assembly and a wheel speed sensor holder of a device for sensing wheel speed according to another exemplary embodiment of the present disclosure.

Referring to FIG. 12, in another embodiment of the present disclosure, in the case of the wheel speed sensor assembly, two sensor elements are not provided in a single sensor body, but may be provided independently.

A modified example of the present disclosure may include a first wheel speed sensor 210a and a second wheel speed sensor 210b.

In a modified example, the first wheel speed sensor 210a may include a first sensor body 212a in which a first sensor element 211a is disposed, and first and second lead frames 213a and 214a electrically connected to the first sensor element 211a and extending to the outside of the first sensor body 212a.

In a modified example, the second wheel speed sensor 210b may include a second sensor body 212b in which a second sensor element 211b is disposed, and third and fourth lead frames 213b and 214b electrically connected to the second sensor element 211b and extending to the outside of the second sensor body 212b.

In a modified example, the wheel speed sensor holder 220 may include a seating part 221 and a support part 222.

The seating part 221 accommodates the first wheel speed sensor 210a and the second wheel speed sensor 210b. The first wheel speed sensor 210a and the second wheel speed sensor 210b may be seated on the seating part 221.

In a modified example of an embodiment of the present disclosure, the seating part 221 may include a sensor seating plate 221a on which a bottom surface of the first wheel speed sensor 210a and the second wheel speed sensor 210b are seated, and a sensor support sidewall 221b protruding upward from the sensor seating plate 221a to support the side surfaces of the first wheel speed sensor 210a and the second wheel speed sensor 210b.

The sensor support sidewall 221b may be provided to surround or cover the remaining portions of the side surfaces of the first wheel speed sensor 210a and the second wheel speed sensor 210b except for a portion where the lead frame extends.

In addition, the seating part 221 may further include an intermediate wall 221c that divides a portion of the sensor seating plate 221a on which the first wheel speed sensor 210a and the second wheel speed sensor 210b are seated.

The support part 222 is connected to the seating part 221. The support part 222 supports the first and second lead frames 213a and 214a, and the third and fourth lead frames 213b and 214b. The support part 222 may have a shorter length than the first and second lead frames 213a and 214a, and the third and fourth lead frames 213b and 214b.

The support part 222 may include a lead frame support plate 222a supporting the first to fourth lead frames 213a, 214a, 213b, and 214b, and a plurality of lead frame support sidewalls 222b, 222c, and 222d protruding upward from the lead frame support plate 222a to support side surfaces of the first to fourth lead frames 213a, 214a, 213b, and 214b between the first lead frame 213a and the second lead frame 214a, between the second lead frame 214a and the third lead frame 213b, and between the third lead frame 213b and the fourth lead frame 214b.

In a modified example of an embodiment of the present disclosure, the wheel speed sensor holder 220 may have one or more side beams 223. The side beam 223 may be disposed to extend laterally from both sides of the seating part 221 or the support part 222. For example, the side beam 223 may be disposed to extend laterally from both sides of the lead frame support plate 222a. The side beam 223 may be used to fix the housing in a mold when molding the housing.

According to the above configuration, the device for sensing wheel speed according to an aspect of the present disclosure can efficiently achieve connection between a wheel speed sensor assembly and a cable through a connection member or connector.

In addition, the device for sensing wheel speed according to an aspect of the present disclosure may facilitate connection between a cable and a lead frame through a wheel speed sensor holder configured to expose the lead frame of a wheel speed sensor assembly to the outside.

In addition, the device for sensing wheel speed according to an aspect of the present disclosure can efficiently achieve connection between a wheel speed sensor assembly and a cable through a structure in which a lead frame of a wheel speed sensor assembly is inserted into a connection member or connector while the cable and the connection member or connector are coupled to a cable holder.

In addition, the device for sensing wheel speed according to an aspect of the present disclosure can effectively achieve connection between a plurality of sensor elements and a plurality of cables, arrangement and alignment of a plurality of cables through an additional sheathing member and a cable holder.

It should be understood that the effects of the present disclosure are not limited to the above-described effects, and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A device for sensing wheel speed, comprising:
a wheel speed sensor assembly having a sensor body in which a first sensor element configured to sense a wheel speed of a vehicle is embedded, and a first lead frame electrically connected to the first sensor element embedded in the sensor body and extending to an outside of the sensor body;
a first cable having a first conductive wire electrically connected to the first lead frame and a first sheath covering the first conductive wire; and
a first connector covering at least a part of the first lead frame and one end of the first conductive wire that is exposed out of one end of the first sheath of the first cable and is disposed to contact the first lead frame, and fixedly supporting the first lead frame and the first conductive wire such that the first lead frame and the first conductive wire are fixed to be contacted with each other.

2. The device for sensing wheel speed of claim 1, wherein the first connector has a first connection body, and a first connection hole penetrating one side and another side of the first connection body, wherein the first lead frame and the one end of the first conductive wire are disposed to be contacted with each other in the first connection hole.

3. The device for sensing wheel speed of claim 2, wherein the first connection body has a substantially rectangular box shape, and the first connection hole has a substantially rectangular shape.

4. The device for sensing wheel speed of claim 1,
wherein the wheel speed sensor assembly further has a second lead frame electrically connected to the first sensor element and extending to the outside of the sensor body, and
wherein the device for sensing wheel speed further comprises:
a second cable having a second conductive wire electrically connected to the second lead frame and a second sheath covering the second conductive wire; and
a second connector covering the second lead frame and one end of the second conductive wire that is exposed out of one end of the second sheath of the second cable and is disposed to contact the second lead frame, and fixedly supporting the second lead frame and the second conductive wire such that the second lead frame and the second conductive wire are fixed to be contacted with each other.

5. The device for sensing wheel speed of claim 4, wherein the first connector and the second connector are arranged side by side.

6. The device for sensing wheel speed of claim 4, further comprising a wheel speed sensor holder on which the wheel speed sensor assembly is seated.

7. The device for sensing wheel speed of claim 6, wherein the wheel speed sensor holder comprises:
a seat part on which the sensor body is seated; and
a support part connected to the seat part and supporting the first and second lead frames.

8. The device for sensing wheel speed of claim 7, wherein a length of the support part is shorter than lengths of the first and second lead frames.

9. The device for sensing wheel speed of claim 4, further comprising a cable holder on which the first and second cables are seated.

10. The device for sensing wheel speed of claim 9, wherein the first and second connectors are fixedly disposed in the cable holder.

11. The device for sensing wheel speed of claim 10, wherein the cable holder comprises a connection part having first and second through holes, wherein the first and second lead frames are disposed in first ends of the first and second through holes of the connection part, respectively, the first and second conductive wires are disposed in second ends of the first and second through holes of the connection part, respectively, and the first and second connectors are fixedly disposed in the first and second through holes of the connection part, respectively.

12. The device for sensing wheel speed of claim 11, wherein the cable holder further comprises a cable support part connected to the second ends of the connection part and extending to support the first and second cables.

13. A device for sensing wheel speed, comprising:
a wheel speed sensor assembly having a sensor body in which a first sensor element and a second sensor element configured to sense a wheel speed of a vehicle which are embedded, and first and second lead frames electrically connected to the first sensor element and extending to an outside of the sensor body, and third and fourth lead frames electrically connected to the second sensor element and extending to the outside of the sensor body;
a first cable having a first conductive wire electrically connected to the first lead frame and a first sheath covering the first conductive wire;
a second cable having a second conductive wire electrically connected to the second lead frame and a second sheath covering the second conductive wire;
a third cable having a third conductive wire electrically connected to the third lead frame and a third sheath covering the third conductive wire;
a fourth cable having a fourth conductive wire electrically connected to the fourth lead frame and a fourth sheath covering the fourth conductive wire;
a first connector covering at least a part of the first lead frame and one end of the first conductive wire that is exposed out of one end of the first sheath of the first cable and is disposed to contact the first lead frame, and fixedly supporting the first lead frame and the first conductive wire such that the first lead frame and the first conductive wire are fixed to be contacted with each other;
a second connector covering at least a part of the second lead frame and one end of the second conductive wire that is exposed out of one end of the second sheath of the second cable and is disposed to contact the second lead frame, and fixedly supporting the second lead frame and the second conductive wire such that the second lead frame and the second conductive wire are fixed to be contacted with each other;
a third connector covering at least a part of the third lead frame and one end of the third conductive wire that is exposed out of one end of the third sheath of the third cable and is disposed to contact the third lead frame, and fixedly supporting the third lead frame and the third conductive wire such that the third lead frame and the third conductive wire are fixed to be contacted with each other;
a fourth connector covering at least a part of the fourth lead frame and one end of the fourth conductive wire that is exposed out of one end of the fourth sheath of the fourth cable and is disposed to contact the fourth lead frame, and fixedly supporting the fourth lead frame and the fourth conductive wire such that the fourth lead frame and the fourth conductive wire are fixed to be contacted with each other; and
a cable holder having a connection part having first to fourth through holes, wherein the first to fourth lead frames are disposed in first ends of the first to fourth through holes of the connection part, respectively, the first to fourth conductive wires are disposed in second ends of the first to fourth through holes of the connection part, respectively.

14. The device for sensing wheel speed of claim 13, wherein the first to fourth connectors are fixedly disposed in the first to fourth through holes, respectively.

15. The device for sensing wheel speed of claim 13, wherein the first to fourth connectors are arranged side by side.

16. The device for sensing wheel speed of claim 13,
wherein the first connector has a first connection body, and a first connection hole penetrating one side and another side of the first connection body, wherein the first lead frame and the one end of the first conductive wire are disposed to be contacted with each other in the first connection hole, and
the second to fourth connectors have second to fourth connection bodies corresponding to the first connection body, and second to fourth connection holes corresponding to the first connection hole, respectively.

17. The device for sensing wheel speed of claim 16, wherein the first connection body has a substantially rectangular box shape, and the first connection hole has a substantially rectangular shape.

18. The device for sensing wheel speed of claim 13, further comprising a wheel speed sensor holder on which the wheel speed sensor assembly is seated.

19. The device for sensing wheel speed of claim 18, wherein the wheel speed sensor holder comprises:
a seat part on which the sensor body is seated; and
a support part connected to the seat part and supporting the first to fourth lead frames.

20. The device for sensing wheel speed of claim 19, wherein a length of the support part is shorter than lengths of the first to fourth lead frames.
